(19) United States
(12) Patent Application Publication
(10) Pub. No.: US 2024/0367381 A1
(43) Pub. Date: Nov. 7, 2024

(54) 3D PRINTING PHYSICAL OBJECT INFUSION

(71) Applicant: INTERNATIONAL BUSINESS MACHINES CORPORATION, ARMONK, NY (US)

(72) Inventors: Logan Bailey, Atlanta, GA (US); Zachary A. Silverstein, Georgetown, TX (US); Kelley Anders, East New Market, MD (US); Sarbajit K. Rakshit, Kolkata (IN)

(21) Appl. No.: 18/311,328

(22) Filed: May 3, 2023

(51) Int. Cl. B29C 64/386; B29C 64/118; B29C 64/40; B33Y 10/00; B33Y 50/00; G06T 17/00

(52) U.S. Cl. CPC B29C 64/386; B29C 64/118; B29C 64/40; B33Y 10/00; B33Y 50/00; G06T 17/00

(57) ABSTRACT

According to one embodiment, a method, computer system, and computer program product for 3D printing is provided. The present invention may include identifying one or more physical objects to be infused within an object being 3D printed; generating at least one digital model of the one or more identified physical objects; analyzing a digital model of the object being 3D printed; determining one or more identified physical object that can be infused within the object being 3D printed; modifying the digital model of the object being 3D printed to comprise an internal physical object infused within the object being 3D printed; and printing the object being 3D printed over the internal physical object. Additionally, according to one embodiment, a method for manufacturing a three-dimensional product is provided. Additionally, according to one embodiment, a data processing device for 3D printing is provided.

### BACKGROUND

The present invention relates, generally, to the field of computing, and more particularly to 3D printing.

3D printing is a technology that is used to construct a three-dimensional object (3D object) from a digital model. 3D printing is performed in processes in which material is deposited, and joined or solidified under computer control, with material typically being added together layer by layer. Currently, 3D printing can be performed by printing a 3D object with physically recycled material. However, in order for true optimization of the 3D printing process, a method and system by which physical objects can be examined to determine if the physical object(s) can be infused inside a 3D object to be printed, are needed. Thus, an improvement in 3D printing has the potential to benefit a user, the 3D printing process, and 3D printed products by reducing costs, reducing waste, and optimizing printing time.

### SUMMARY

Embodiments of a method, a computer system, and a computer program product are described. According to one embodiment, a method, computer system, and a computer program product for 3D printing is provided. Additionally, according to one embodiment, a method for manufacturing a three-dimensional product is provided. The present invention may include identifying one or more physical objects to be infused within an object being 3D printed. The present invention may include generating at least one digital model of the one or more identified physical objects. The present invention may include analyzing a digital model of the object being 3D printed. The present invention may include determining one or more identified physical objects that can be infused within the object being 3D printed. The present invention may include modifying the digital model of the object being 3D printed to comprise an internal physical object infused within the object being 3D printed. The present invention may include printing the object being 3D printed over the internal physical object. The present invention provides the advantages of saving time, space, and materials during 3D printing. A permissive embodiment of the present invention may include scanning a surrounding environment. A permissive embodiment of the present invention may include enlarging the identified physical object. A permissible embodiment of the present invention may include determining an optimal application for an identified physical object. A permissive embodiment of the present invention may include printing filament and/or support material on the 3D printed object to further support and balance the 3D printed object. A permissive embodiment of the present invention may include printing filament and/or support material on the 3D printed object to increase dimensions of the 3D printed object. Additionally, according to one embodiment, a data processing device for 3D printing is provided, which may include at least one 3D printer; a digital model of an object to be 3D printed; one or more physical objects to be infused within a 3D printed object; and at least one augmented reality device. Also, the present invention provides the additional benefits of both reducing the cost of 3D printing and the waste generated during 3D printing.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates an exemplary networked computer environment according to at least one embodiment;

FIG. 2 illustrates an exemplary application invention environment according to at least one embodiment;

FIG. 3 is an operational flowchart illustrating 3D printing object infusion determination process according to at least one embodiment; and

FIG. 4 is a system diagram illustrating an exemplary program environment of an implementation of a 3D printing object infusion determination process according to at least one embodiment.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

In 3D printing, it may be likely that there are partial, incomplete, or unused 3D prints lying around a printing area, such as an office or a basement. Furthermore, there may additionally be unused physical items lying around a household. It may be likely that these partial, incomplete, unused 3D prints, and unused physical items are disposed of, generating waste. Additionally, 3D print time may not be optimized because further 3D object prints are likely to be started completely from scratch, thus using more 3D printing materials, such as filament. To further reduce the cost of 3D printing, there is a need to further reduce the amount of new material used, and thus, the costs of the 3D printing process and 3D print time, by reusing old 3D printed products and unused physical objects.

Currently, the prior art attempts to both reduce the costs of 3D printing and accelerate the 3D printing process in various methods. One way in which current methods attempt to address problems with reducing waste and optimizing print time during 3D printing is by physically recycling material to use in 3D printing. For example, leftover/unused material may be melted down and restrung so that the material may be reused to 3D print an object. However, the process of melting down and restringing 3D printing material requires ample time and still wastes material as material is lost during the melting down and restringing processes. Another way in which current methods attempt to address problems with reducing waste and optimizing print time during 3D printing is by using a photopolymerization method during the printing of a 3D object. A photopolymerization method can be used to embed an internal object using materials with the flexibility of a range of mechanical and optical properties. However, using a photopolymerization method remains costly, has a lengthy post-processing time, and often requires additional support structures and post-curing for a 3D object in order for the 3D object to have enough structural support for use. Therefore, shortcomings still remain in the area of 3D printing. It is important to both minimize 3D print time and reduce the amount of waste generated during a 3D print. Thus, an improvement in 3D printing has the potential to benefit the 3D printing process and 3D printed products by reducing costs, reducing waste, and optimizing print time.

The present invention can remedy the above-mentioned deficiencies in the prior art by retrieving and cross-validating the coordinates, sizing, and any other physical attributes of possible physical objects to be infused within an object to be 3D printed. The infused object can be captured using a visual scan, and the present invention can calculate the differences in printing the 3D object with and without the infused object, the amount of material needed and the cost of the material with and without the 3D object, and the amount of time needed to 3D print the 3D object with and without the infused object, using a slicing software. The present invention can determine the dimensions and shape of any physical object that is scanned and can create a digital model of the physical object. The present invention may modify the digital model of the object to be 3D printed to comprise the infused object within the object to be 3D printed, based on various considerations such as structural modeling, object placement, print head location, and printer alignment. The present invention may modify structural components of the digital object for slight shape changes, angle modifications, sizing modifications, and/or structural needs. Also, the present invention may modify a physical object by adding material and thus, enlarging the physical object. Additionally, the present invention may print the object to be 3D printed based on the modified digital object comprising the object to be 3D printed and the infused object.

The present invention has the capacity to improve 3D printing by dynamically using physical objects in a new 3D print in which the new 3D print is printed over the physical object, as to infuse the physical object. The present invention can analyze physical objects and digital 3D models of a 3D object and determine if the 3D object may be printed over and/or on one or more of the physical objects. This improvement in 3D printing can be accomplished by implementing a system that identifies one or more physical objects in the scan of the surrounding environment, generates at least one digital model of the one or more identified physical objects, analyzes a digital model of an object being 3D printed, determines one or more identified physical object that can be infused within the object being 3D printed, modifies the digital model of the object being 3D printed to comprise an internal physical object infused within the object being 3D printed, and prints the object being 3D printed over the internal physical object. An embodiment in which the system scans a surrounding environment of a user to identify physical objects has the advantage of further providing physical objects that can be recycled and reused. An embodiment in which the system enlarges the identified physical object is also useful for the added versatility of physical objects in their ability to be infused within an object being 3D printed.

In some embodiments of the invention, the 3D printing object infusion determination program, herein referred to as “the program”, can scan a surrounding environment using a 3D printer, 3D scanner, and/or an augmented device. The surrounding environment can be a user's real-world surroundings. The surrounding environment may comprise physical objects. Physical objects may be infused within an object to be 3D printed during the 3D printing process. A physical object that is infused within a 3D object may comprise a physical object that is either completely or partially enclosed within a 3D object during the printing of the 3D object. A user may be any person who is using the program.

The program can identify one or more physical objects in the scan of the surrounding environment. The program can recognize physical objects in the surrounding environment. The program can recognize physical objects by performing object recognition using the AR device, and additionally, 3D printer(s) or 3D scanner(s) with cameras embedded within them. The program can identify the dimensions and shape of any physical object in the user's surrounding environment using a visual scan. A physical object can be a real-world object, and may be either two-dimensional or three-dimensional. Additionally, the program may identify physical object(s) that a user desires to use as part of a 3D print based on the inputs of a user on the graphical user interface (“GUI”). A user may input the name of the physical object and the physical object's size, dimensions, and other physical attributes, such as density, weight, etc. Based on the inputted information, the program may create a digital model of the physical object. Also, the program may identify one or more physical objects from a user's printing history, stereolithography (“STL”) files, or CAD files.

The program can generate digital models of the one or more identified physical objects in the scanned surrounding environment. This can be performed by using the measured size, dimensions, and other physical attributes of the physical objects. In some embodiments of the invention, the measured size and dimensions of a physical object may be inputted by a user using the GUI.

The program can analyze a digital model, such as a CAD file or an STL file, of an object being 3D printed to determine the dimensions, shape, axis, and other physical attributes of the object being 3D printed. A user may select a CAD model of an object being 3D printed, otherwise referred to as the 3D object, from the client computing device and/or database for the program to analyze. The program can generate a digital model of the 3D object based on the analyzed CAD model of the 3D object.

The program can determine one or more identified physical objects that can be infused within the 3D object, otherwise referred to as an internal physical object, by cross-validating the coordinates, sizing, density, dimensions, solidity, and other physical attributes of the identified physical objects with the coordinates, sizing, density, dimensions, solidity, and other physical attributes of the object to be 3D printed. Additionally, the program can calculate the difference(s) between printing the 3D object without a physical object infused within the 3D object and printing the physical object infused within the 3D object, by using a slicing software. The program can calculate the amount of material, the cost of the material, and the amount of printing time that can be saved if a physical object is infused within the 3D object. The program can rank the identified physical objects for use as internal physical objects within the 3D object based on factors such as the amount of material used, the cost of the material, and the estimated printing time of the 3D object, etc. In some embodiments of the invention, the program may scan a physical object and determine the optimal application for the physical object to be infused within a 3D object and may prioritize certain physical objects for use over other physical objects.

In some embodiments of the invention, the program may enlarge the identified physical object. The program may determine that an identified physical object needs to be enlarged if the program identifies that an additional layer(s) of material over the identified physical object would make it suitable to be infused within the object to be 3D printed. The program may identify an appropriate combination of different filaments and support materials to enlarge the size of a physical object.

The program can modify the digital model of the 3D object to comprise an internal physical object infused within the 3D object, based on the identified physical object that will be infused within the 3D object. Modifying the digital model of the 3D object may comprise modifying the structural components of the digital model for shape changes, angle modifications, sizing modifications, structural needs, etc. Additionally, modifying the digital model of the 3D object may comprise considering structural modeling, physical object placement on the printing surface, 3D print head(s) location, and print alignment recommendation(s). The program can dynamically save the data representing the modifications and the digital model of the 3D object comprising the modifications in the database. The program can send the modified digital model of the 3D object to the 3D printer(s). In embodiments where there is more than one internal physical object infused within the 3D object, the program may modify the digital model of the 3D object to comprise the internal physical objects infused within the 3D object.

The program can print the 3D object over the internal physical object. The program may feed the data representing the modified digital model of the 3D object to the 3D printer(s) with instructions instructing the 3D printer(s) to print the 3D object. The program can print the 3D object based on the instructions the program sent to the 3D printer(s). The program may instruct the user on where to place the physical object on the 3D printing tray. The program may confirm the location of the physical object using a visual scan, based on the physical object's geospatial dimensions. Multiple printing nozzles may be used to print the 3D object through the use of different individual filaments and/or filament mixtures loaded into each printing nozzle. In some embodiments of the invention, the program may use multiple 3D printers to print the 3D object.

An exemplary use of the invention may involve 3D printing in a user's kitchen. The program may scan the user's kitchen using an AR device and one or more 3D scanners to find physical objects that may be infused inside an object to be 3D printed. The program detects that the object to be 3D printed is a doorstop. The program analyzes the CAD file of the doorstop and determines the size and dimensions of the doorstop to be 3D printed. Based on the scan of the user's kitchen, the program identifies a mug that can be infused inside the 3D-printed doorstop based on the size and dimensions of both the mug and the doorstop to be 3D printed. Thus, the program modifies the digital file of the doorstop to comprise the size and dimensions of the mug infused within the doorstop. The program may 3D print the doorstop over and around the mug, saving both time and material.

Another exemplary use of the invention may involve a hollow physical object, like a mug, being infused inside an object to be 3D printed. Additionally, other physical objects are identified, such as a small headphone case, to be inserted into the hollow space in the mug and printed over with filament, to increase the density of the mug.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The following described exemplary embodiments provide a system, method, and program product to identify one or more physical objects to be infused within the object being 3D printed, generate at least one digital model of the one or more identified physical objects, analyze a digital model of an object being 3D printed, determine one or more identified physical object that can be infused within the object being 3D printed, modify the digital model of the object being 3D printed to comprise an internal physical object infused within the object being 3D printed, and print the object being 3D printed over the internal physical object. Additionally, the following described exemplary embodiments provide a system, method, and program product to scan a surrounding environment and identify one or more physical objects to be infused within an object being 3D printed in the surrounding environment. Additionally, the following described exemplary embodiments provide a system, method, and program product to enlarge the identified physical object. Additionally, the following described exemplary embodiments provide a system, method, and program product to determine an optimal application for an identified physical object. Additionally, the following described exemplary embodiments provide a system, method, and program product to print filament and/or support material on the 3D printed object to further support and balance the 3D printed object. Additionally, the following described exemplary embodiments provide a system, method, and program product to print filament and/or support material on the 3D printed object to increase the dimensions of the 3D printed object.

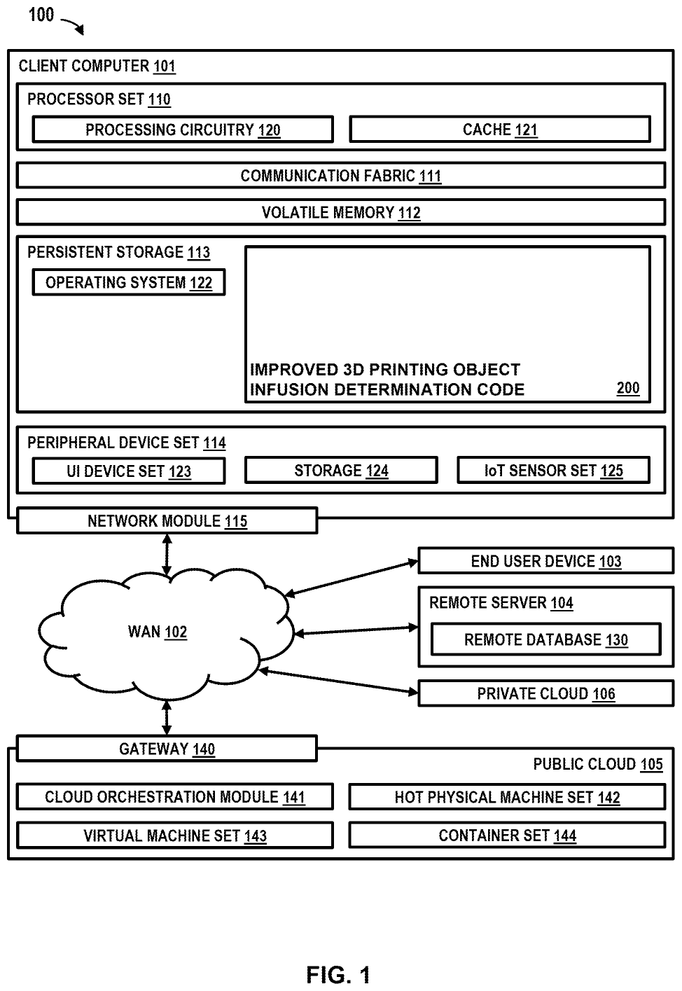

Referring to FIG. 1, an exemplary networked computer environment 100 is depicted, according to at least one embodiment. Computing environment 100 contains an example of an environment for the execution of at least some of the computer code involved in performing the inventive methods, such as improved 3D printing object infusion determination code 200. In addition to code block 200 computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and code block 200, as identified above), peripheral device set 114 (including user interface (UI), device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby affect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in code block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in code block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

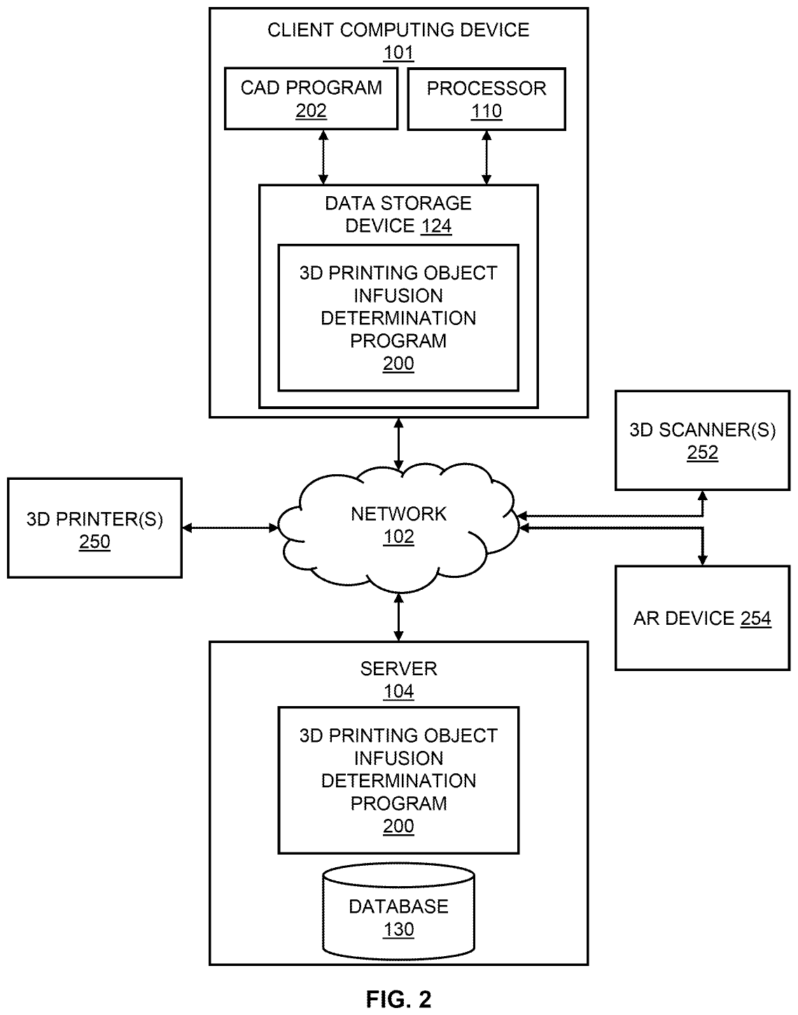

Referring to FIG. 2, an exemplary application environment is depicted, according to at least one embodiment. FIG. 2 may include client computing device 101 and a remote server 104 interconnected via a communication network 102. According to at least one implementation, FIG. 2 may include a plurality of client computing devices 101 and remote servers 104, of which only one of each is shown for illustrative brevity. It may be appreciated that FIG. 2 provides only an illustration of one implementation and does not imply any limitations with regard to the environments in which different embodiments may be implemented. Many modifications to the depicted environments may be made based on design and implementation requirements.

Client computing device 101 may include a processor 110 and a data storage device 124 that is enabled to host and run a 3D printing object infusion determination program 200 and communicate with the remote server 104 via the communication network 102, in accordance with one embodiment of the invention.

The remote server computer 104 may be a laptop computer, netbook computer, personal computer (PC), a desktop computer, or any programmable electronic device or any network of programmable electronic devices capable of hosting and running a 3D printing object infusion determination program 200 and a database 130 and communicating with the client computing device 101 via the communication network 102, in accordance with embodiments of the invention. The remote server 104 may also operate in a cloud computing service model, such as Software as a Service (SaaS), Platform as a Service (PaaS), or Infrastructure as a Service (IaaS). The remote server 104 may also be located in a cloud computing deployment model, such as a private cloud, community cloud, public cloud, or hybrid cloud.

The database 130 may be a digital repository capable of data storage and data retrieval. The database 130 can be present in the remote server 104 and/or any other location in the network 102. The database 130 can store 3D digital models and the information outputted from the CAD module 406. The database 130 may store information relating to object recognition. The database 130 may comprise the physical object manual corpus. The physical object manual corpus may comprise the inventory of physical objects in a user's surroundings, along with the size, dimensions, and other physical features of the physical objects, such as density or infill. The inventory of physical objects may be updated manually by a user's inputs and/or dynamically by the 3D scanner(s) 252 and/or augmented reality device(s) 254. The inventory of physical objects may comprise the availability status of physical objects, such as if a physical object is being used by the user or if a physical object is no longer being used by a user and is available to be used in 3D printing. The corpus may comprise information relating to the filaments used to 3D print. Additionally, the corpus may comprise information relating to the success/failure of a 3D print, such as whether a certain object was able to be successfully or unsuccessfully infused within a 3D print. Also, the database 130 may comprise a user's printing history.

3D printer 250 may be any device capable of constructing a 3D object from a CAD model or other digital 3D model. Additionally, the 3D printer 250 may comprise one or more cameras, such as a physical or virtual camera, and/or sensors, such as accelerometers, gyroscopes, magnetometers, proximity sensors, pressure sensors, etc., embedded into the 3D printer 250.

3D scanner 252 may be any device capable of scanning a 3D object. The 3D scanner 252 may determine the shape and dimensions of a 3D object using object recognition and may determine the relative positioning of the 3D object. Additionally, the 3D scanner 252 may comprise one or more cameras, such as any device capable of recording visual images in the form of photographs, films, or video signals, such as a physical or virtual camera, and/or sensors, such as accelerometers, gyroscopes, magnetometers, proximity sensors, pressure sensors, etc., embedded into the 3D scanner 252.

Augmented reality (AR) device 254 may be any device or combination of devices enabled to record real-world information that the AR module 408 may overlay with computer-generated perceptual elements to create an AR environment. The AR device 254 can display an AR-simulated environment to a user and allow the user to interact with the AR environment. The AR device 254 can be a headset. Also, the AR device 254 can comprise a head-mounted display (HMD). Additionally, the AR device 254 may be equipped with or comprise a number of sensors, such as a camera, microphone, and accelerometer, and these sensors may be equipped with or comprise a number of user interface devices such as touchscreens, speakers. etc.

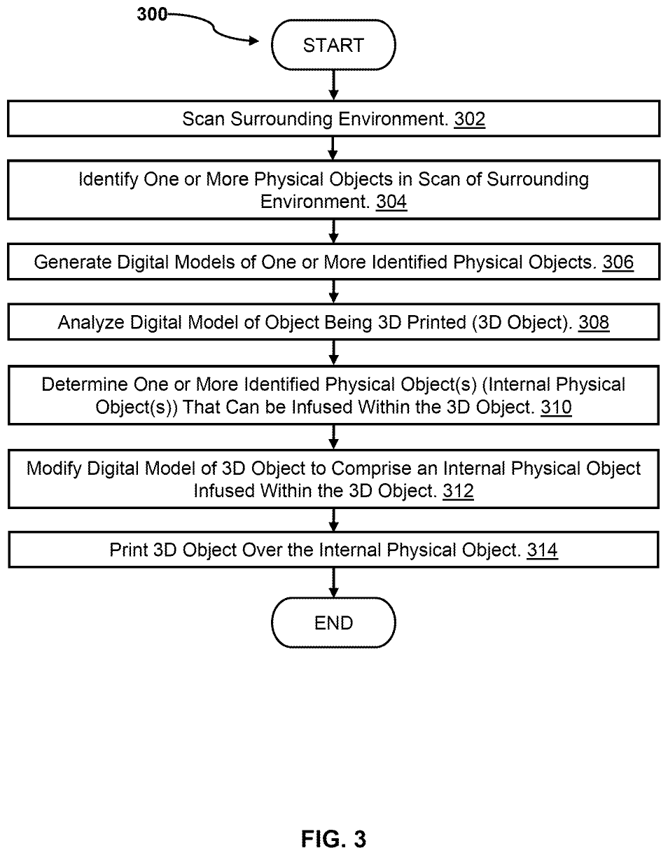

According to the present embodiment, the 3D printing object infusion determination program 200 herein referred to as “the program”, may be a program capable of scanning a surrounding environment, identifying one or more physical objects in the scan of the surrounding environment, generating digital models of the one or more identified physical objects in the scanned surrounded area, analyzing a digital model of an object being 3D printed, determining an identified physical object that can be infused within the 3D object, modifying the digital model of the 3D object to comprise an internal physical object infused within the 3D object, and printing the 3D object over the internal physical object. The program 200 may be located on client computing device 101 or remote server 104 or on any other device located within network 102. Furthermore, the program 200 may be distributed in its operation over multiple devices, such as client computing device 101 and remote server 104. The 3D printing object infusion determination method is explained in further detail below with respect to FIG. 3.

Referring now to FIG. 3, an operational flowchart illustrating a 3D printing object infusion determination process 300 is depicted according to at least one embodiment. At 302, the program 200 scans a surrounding environment. The program 200 can scan a surrounding environment using a 3D printer 250, 3D scanner 252, and/or an augmented device 254. The surrounding environment can be a user's real-world surroundings. The surrounding environment may comprise physical objects. Physical objects may be infused within an object to be 3D printed during the 3D printing process. A physical object that is infused within a 3D object may comprise a physical object that is either completely or partially enclosed within a 3D object during the printing of the 3D object. A user may be any person who is using the program 200.

At 304, the program 200 identifies one or more physical objects in the scan of the surrounding environment. The program 200 can recognize physical objects in the surrounding environment. The program 200 can recognize physical objects by performing object recognition using the AR device 254, and additionally, 3D printer(s) 250 or 3D scanner(s) 252 with cameras embedded within them. The program 200 can identify the dimensions and shape of any physical object in the user's surrounding environment using a visual scan. A physical object can be a real-world object, and may be either two-dimensional or three-dimensional. Additionally, the program 200 may identify physical object(s) that a user desires to use as part of a 3D print based on the inputs of a user on the graphical user interface (“GUI”). A user may input the name of the physical object and the physical object's size, dimensions, and other physical attributes, such as density, weight, etc. Based on the inputted information, the program 200 may create a digital model of the physical object. For example, the user may enter the dimensions, shape, and other physical attributes of a cup, and the program 200 may generate a digital model of the cup based on the information from the physical attributes that the user inputted. Also, the program 200 may identify one or more physical objects from a user's printing history, stereolithography (“STL”) files, or CAD files.

At 306, the program 200 generates digital models of the one or more identified physical objects in the scanned surrounded area. The program 200 can generate digital models of the identified physical objects using the measured size, dimensions, and other physical attributes of the physical objects. In some embodiments of the invention, the measured size and dimensions of a physical object may be inputted by a user using the GUI. The program 200 can save the digital models of physical objects in the database 130.

At 308, the program 200 analyzes a digital model of an object being 3D printed. The program 200 can analyze a digital model, such as a CAD file or an STL file, of the object being 3D printed to determine the dimensions, shape, axis, and other physical attributes of the object being 3D printed. A user may select a CAD model of an object being 3D printed, otherwise referred to as the 3D object, from the client computing device 101 and/or database 130 for the program 200 to analyze. The program 200 can receive the CAD model information through network communications 102 with a CAD program 202. The program 200 can generate a digital model of the 3D object based on the analyzed CAD model of the 3D object.

At 310, the program 200 determines one or more identified physical objects that can be infused within the 3D object. The program 200 may determine an identified physical object that can be infused within the 3D object, otherwise referred to as an internal physical object, by cross-validating the coordinates, sizing, density, dimensions, solidity, and other physical attributes of the identified physical objects with the coordinates, sizing, density, dimensions, solidity, and other physical attributes of the object to be 3D printed. For example, the program 200 may determine that one or more identified physical objects may be infused within a 3D object via a cutout space in the 3D object, based on the smaller size and strong structural support of the identified physical objects. Also, for example, the program 200 may determine that an identified physical object may be infused entirely within a 3D object based on the identified physical object's smaller size and similar shape to the 3D object. Additionally, the program 200 can calculate the difference(s) between printing the 3D object without a physical object infused within the 3D object and with printing the physical object infused within the 3D object, by using a slicing software. The program 200 can calculate the amount of material, the cost of the material, and the amount of printing time that can be saved if a physical object is infused within the 3D object. The program 200 can rank the identified physical objects for use as internal physical objects within the 3D object based on factors such as the amount of material used, the cost of the material, and the estimated printing time of the 3D object, etc.

In some embodiments of the invention, the program 200 may enlarge the identified physical object. The program 200 may determine that an identified physical object needs to be enlarged if the program 200 identifies that an additional layer(s) of material over the identified physical object would make it suitable to be infused within the object to be 3D printed. The program 200 may identify an appropriate combination of different filaments and support materials to enlarge the size of a physical object. For example, a user may have purchased a physical object and found the physical object to be smaller than expected when it arrived. The program 200 may 3D print an appropriate combination of filament and support materials to increase the dimensions of the physical object.

In some embodiments of the invention, the program 200 may scan a physical object and determine the optimal application for the physical object to be infused within a 3D object. For example, the program 200 may scan both an empty liquid soap bottle and a plastic water bottle. The program 200 may determine that the empty liquid soap bottle may be structurally stronger than the plastic water bottle but that liquid soap residue remaining in the empty liquid soap bottle may compromise the structural integrity of the 3D object. Thus, the program 200 may prioritize the plastic water bottle for use over the empty liquid soap bottle.

At 312, the program 200 modifies the digital model of the 3D object to comprise an internal physical object infused within the 3D object. The program 200 may modify the digital model of the 3D object based on the identified physical object that will be infused within the 3D object. Modifying the digital model of the 3D object may comprise modifying the structural components of the digital model for shape changes, angle modifications, sizing modifications, structural needs, etc. For example, the program 200 may modify the digital model of the 3D object to comprise a cutout space into which the identified physical object can be inserted. Also, for example, the program 200 may modify the digital model of the 3D object to comprise the entire identified physical object infused within the 3D object. Additionally, modifying the digital model of the 3D object may comprise considering structural modeling, physical object placement on the printing surface, 3D print head(s) location, and print alignment recommendation(s). The program 200 can dynamically save the data representing the modifications and the digital model of the 3D object comprising the modifications in the database 130. The program 200 can send the modified digital model of the 3D object to the 3D printer(s) 250. In embodiments where there is more than one internal physical object infused within the 3D object, the program 200 may modify the digital model of the 3D object to comprise the internal physical objects infused within the 3D object.

At 314, the program 200 prints the 3D object over the internal physical object. The program 200 may feed the data representing the modified digital model of the 3D object to the 3D printer(s) 250 with instructions instructing the 3D printer(s) 250 to print the 3D object. The program 200 can print the 3D object based on the instructions the program 200 sent to the 3D printer(s) 250. The program 200 may instruct the user on where to place the physical object on the 3D printing tray. The program 200 may confirm the location of the physical object using a visual scan, based on the physical object's geospatial dimensions. Multiple printing nozzles may be used to print the 3D object through the use of different individual filaments and/or filament mixtures loaded into each printing nozzle. In some embodiments of the invention, the program 200 may use multiple 3D printers 250 to print the 3D object. When printing is finished, the program 200 can display a prompt to the user, asking if the 3D print was printed successfully. The user may respond to the prompt by selecting “Yes” or “No” and may input comments in a comments box, on the GUI. The program 200 may save the user's response in the database 130.

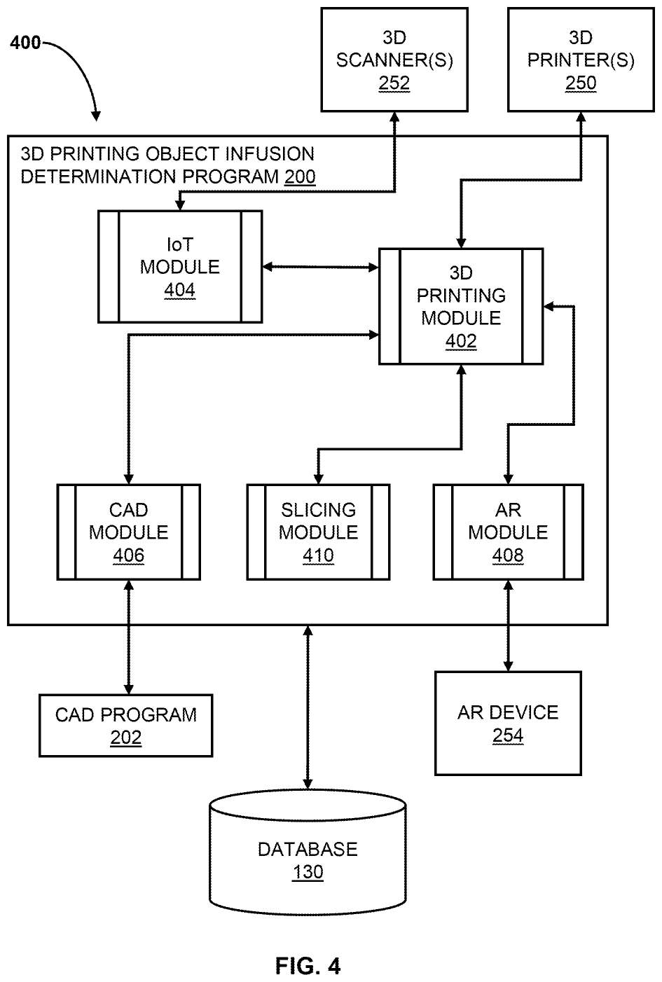

Referring now to FIG. 4, a system diagram illustrating an exemplary program environment 400 of an implementation of a 3D printing object infusion determination process 300 is depicted according to at least one embodiment. Here, the program 200 comprises a 3D printing module 402, an IoT module 404, a CAD module 406, an AR module 408, and a slicing module 410. The exemplary program environment 400 details the interactions between the 3D printing module 402 and the IoT module 404, the 3D printing module 402 and the CAD module 406, the 3D printing module 402 and the AR module 408, and the 3D printing module 402 and the slicing module 410. Additionally, the exemplary program environment 400 details the interactions between the 3D printing module 402 and the 3D printer(s) 250, the IoT module 404 and the 3D scanner(s) 252, the CAD module 406 and the CAD program 202, the AR module 408 and the AR device 254, and the 3D printing object infusion determination program 200 and the database 130.

The 3D printing module 402 may be used to communicate with the 3D printer(s) 250. The IoT module 404 may be used to communicate with the 3D scanner(s) 252. The CAD module 406 may be used to communicate with the CAD program 202. The AR module 408 may be used to display an AR environment and AR objects. The slicing module 410 may be used to transform the digital models into printing instructions and may prepare the 3D models for printing.

It may be appreciated that FIGS. 2 through 4 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A processor-implemented method for 3D printing, the method comprising:
identifying one or more physical objects to be infused within an object being 3D printed;
generating at least one digital model of the one or more identified physical objects;
analyzing a digital model of the object being 3D printed;
determining one or more identified physical objects that can be infused within the object being 3D printed;
modifying the digital model of the object being 3D printed to comprise an internal physical object infused within the object being 3D printed; and
printing the object being 3D printed over the internal physical object.

2. The method of claim 1, further comprising:
scanning a surrounding environment.

3. The method of claim 1, wherein the identified one or more physical objects to be infused within the object being 3D printed are identified using a visual scan and/or from a printing history, an STL file, and/or a CAD file.

4. The method of claim 1, further comprising:
enlarging the identified physical object.

5. The method of claim 4, wherein the enlarging of the identified physical object comprises printing support material and/or filament around positions of the internal physical object before the printing of the object being 3D printed over the internal physical object.

6. The method of claim 1, further comprising:
determining an optimal application for an identified physical object.

7. The method of claim 1, further comprising:
printing filament and/or support material on the 3D printed object to further support and balance the 3D printed object.

8. The method of claim 1, further comprising:
printing filament and/or support material on the 3D printed object to increase dimensions of the 3D printed object.

9. A computer system for 3D printing, the computer system comprising:
one or more processors, one or more computer-readable memories, one or more computer-readable tangible storage medium, and program instructions stored on at least one of the one or more tangible storage medium for execution by at least one of the one or more processors via at least one of the one or more memories, wherein the computer system is capable of performing a method comprising:
identifying one or more physical objects to be infused within an object being 3D printed;
generating at least one digital model of the one or more identified physical objects;
analyzing a digital model of the object being 3D printed;
determining one or more identified physical objects that can be infused within the object being 3D printed;
modifying the digital model of the object being 3D printed to comprise an internal physical object infused within the object being 3D printed; and
printing the object being 3D printed over the internal physical object.

10. The computer system of claim 9, further comprising:
scanning a surrounding environment.

11. The computer system of claim 9, wherein the identified one or more physical objects to be infused within the object being 3D printed are identified using a visual scan and/or from a printing history, an STL file, and/or a CAD file.

12. The computer system of claim 9, further comprising:
enlarging the identified physical object.

13. The computer system of claim 12, wherein the enlarging of the identified physical object comprises printing support material and/or filament around positions of the internal physical object before the printing of the object being 3D printed over the internal physical object.

14. The computer system of claim 9, further comprising:
determining an optimal application for an identified physical object.

15. The computer system of claim 9, further comprising:
printing filament and/or support material on the 3D printed object to further support and balance the 3D printed object.

16. The computer system of claim 9, further comprising:
printing filament and/or support material on the 3D printed object to increase dimensions of the 3D printed object.

17. A computer program product for 3D printing, the computer program product comprising:
one or more computer-readable tangible storage medium and program instructions stored on at least one of the one or more tangible storage medium, the program instructions executable by a processor to cause the processor to perform a method comprising:
identifying one or more physical objects to be infused within an object being 3D printed;
generating at least one digital model of the one or more identified physical objects;
analyzing a digital model of the object being 3D printed;
determining one or more identified physical objects that can be infused within the object being 3D printed;
modifying the digital model of the object being 3D printed to comprise an internal physical object infused within the object being 3D printed; and
printing the object being 3D printed over the internal physical object.

18. The computer program product of claim 17, further comprising:
scanning a surrounding environment.

19. The computer program product of claim 17, wherein the identified one or more physical objects to be infused within the object being 3D printed are identified using a visual scan and/or from a printing history, an STL file, and/or a CAD file.

20. The computer program product of claim 17, further comprising:
enlarging the identified physical object.

21. The computer program product of claim 20, wherein the enlarging of the identified physical object comprises printing support material and/or filament around positions of the internal physical object before the printing of the object being 3D printed over the internal physical object.

22. The computer program product of claim 17, further comprising:
determining an optimal application for an identified physical object.

23. The computer program product of claim 17, further comprising:
printing filament and/or support material on the 3D printed object to further support and balance the 3D printed object.

24. A method for manufacturing a three-dimensional product, the method comprising:
identifying one or more physical objects to be infused within an object being 3D printed;
generating at least one digital model of the one or more identified physical objects;
analyzing a digital model of the object being 3D printed;
determining one or more identified physical objects that can be infused within the object being 3D printed;
modifying the digital model of the object being 3D printed to comprise an internal physical object infused within the object being 3D printed; and
printing the object being 3D printed over the internal physical object.

25. A data processing device for 3D printing, comprising:
at least one 3D printer;
a digital model of an object to be 3D printed;
one or more physical objects to be infused within a 3D printed object; and
at least one augmented reality device.
